(19) United States
(12) Patent Application Publication
(10) Pub. No.: US 2005/0152119 A1
(43) Pub. Date: Jul. 14, 2005

(54) Locking device for heat dissipating device

(75) Inventors: Hsieh-Kun Lee, Tu-Cheng (TW); Cui-Jun Lu, Shenzhen (CN)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry CO., LTD., Tu-Cheng City (TW)

(21) Appl. No.: 10/952,688

(22) Filed: Sep. 29, 2004

(30) Foreign Application Priority Data
Jan. 14, 2004 (CN) 200420015038.8

(51) Int. Cl. H05K 7/20

(52) U.S. Cl. 361/710

(57) ABSTRACT

A locking device for mounting a heat sink to a CPU mounted on a printed circuit board, includes a back plate mounted below the circuit board and having a plurality of posts extending upwardly through the circuit board and the heat sink, and a plurality of retainers. Each retainer includes a pressing section resting on the heat sink, a locking section extending from the pressing section, and an operating section extending from the pressing section and opposing the locking section. Each post is extendable through the pressing section of a corresponding retainer to engage with the locking section.

### TECHNICAL FIELD

The present invention relates to a locking device, and particularly to a locking device which can conveniently mount a heat sink to an electronic component.

### BACKGROUND

As computer technology continues advancing, electronic components such as central processing units (CPUs) of computers are made to provide faster operational speed and greater functional capabilities. When a CPU operates at a high speed in a computer enclosure, its temperature increases greatly and dramatically. It is desirable to dissipate the generated heat quickly, for example, by using a heat sink attached to the CPU in the enclosure. Generally, a locking device is required for mounting the heat sink to the CPU.

FIG. 4 shows a conventional locking device for mounting a heat sink 1 to a CPU 4. The CPU 4 is installed on a printed circiut board 5. A retention module 3 is mounted on the printed circuit board 5 surrounding the CPU 4. The retention module 3 comprises four feet 302 each defining a locking opening 304. The heat sink 1 forms a pair of shoulders 102 on opposite sides thereof. The locking device comprises a pair of clasps 2. Each clasp 2 comprises a beam 202 and a pair of locking legs 204 connected to opposite ends of the beam 202. Each locking leg 204 forms a hook 206 at the bottom end thereof. A handle 210 with a cam formed at one end thereof is pivotably connected to the beam 202. In assembly, the heat sink 1 is attached on the CPU 4 within the retention module 3. The pair of clasps 2 are placed on the shoulders 102 of the heat sink 1. The hooks 206 of the clasps 2 engages in the corresponding locking openings 304 of the retention module 3. The handle 210 is pushed to pivot from a vertical position to a horizontal position to cause the cam of the handle 210 moving to press the heat sink 1 toward the CPU 4, whereby the heat sink 1 is attached to the CPU 4.

However, in assembly, the locking device needs to cooperate with the retention module which surrounds the heat sink 1 and occupies a great space above the printed circuit board where the heat sink 1 can stretch if no retention module is used, which results in the size of the heat sink being limited accordingly. Furthermore, the locking device has a complicated structure which increases the manufacture cost thereof.

### SUMMARY OF THE INVENTION

Accordingly, an object of the present invention is to provide a locking device which occupies small space.

Another object of the present invention is to provide a locking device having a simple structure.

To achieve the above-mentioned objects, a locking device in accordance with a preferred embodiment of the present invention comprises a back plate mounted below a circuit board on which a heat sink is about to be mounted, and a plurality of retainers. The back plate comprises a plurality of posts extending through the circuit board and the heat sink. Each retainer comprises a pressing section resting on the heat sink, a locking section extending from the pressing section, and an operating section extending from the pressing section and opposing the locking section. Each post is extendable through the pressing section of a corresponding retainer to engage with the locking section.

Other objects, advantages and novel features of the present invention will be drawn from the following detailed description of a preferred embodiment of the present invention with attached drawings, in which:

### BRIEF DESCRIPTION OF THE DRAWINGS

FIG. 1 is an exploded, isometric view of a locking device in accordance with a preferred embodiment of the present invention, a heat sink and a CPU mounted on a printed circuit board;

FIG. 2 is an isometric view of a retainer of the locking device of FIG. 1;

FIG. 3 is an assembled view of FIG. 1; and

FIG. 4 shows a conventional locking device for mounting a heat sink to a CPU.

### DETAILED DESCRIPTION OF A PREFERRED EMBODIMENT

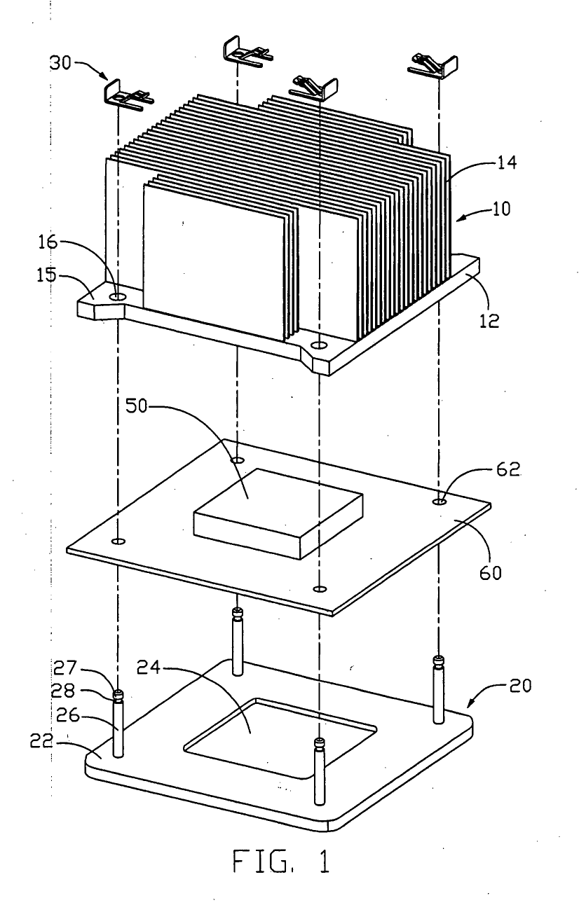

FIG. 1 shows a locking device in accordance with a preferred embodiment of the present invention for mounting a heat sink 10 to a printed circuit board 60. The printed circuit board 60 defines four through holes 62. An electronic component 50, such as a central processing unit (CPU), is installed on the printed circuit board 60 and surrounded by the through holes 62. The heat sink 10 comprises a rectangular base 12 for contacting with the CPU 50 and a plurality of fins 14 extending upwardly from the base 12. The base 12 comprises four mounting sections 15 formed at four corners thereof where no fin 14 is provided. Each mounting section 15 defines a through hole 16 corresponding to one of the through holes 62 of the printed circuit board 60.

The locking device comprises a back plate 20 and four retainers 30. The back plate 20 comprises a body 22 and four posts 26 extending upwardly and perpendicularly from respective corners of the body 22. The body 22 defines an opening 24 in a center thereof for reducing the weight of the body 22. Each post 26 comprises a head 27 formed at the top end thereof and a neck 28 formed below the head 27.

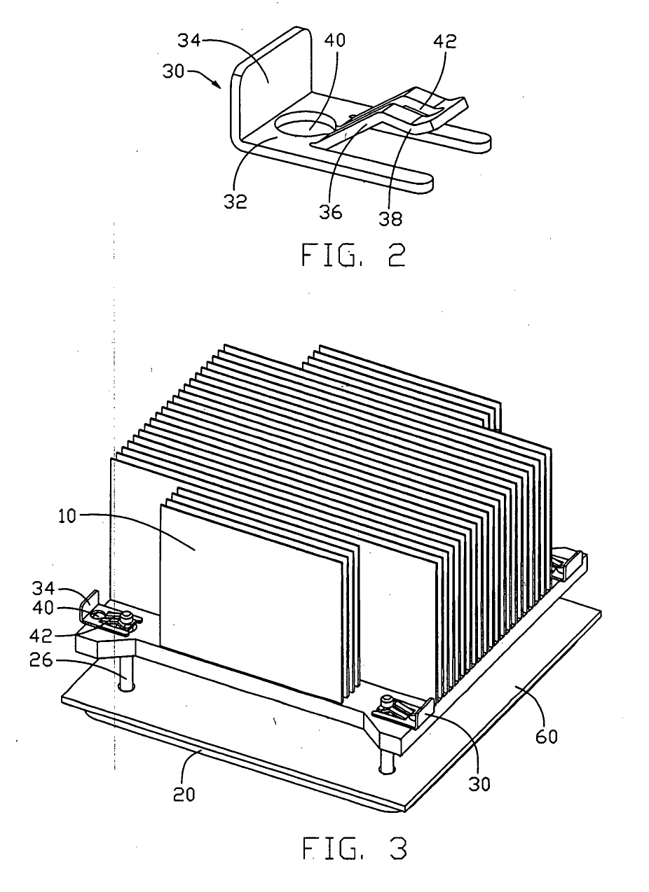

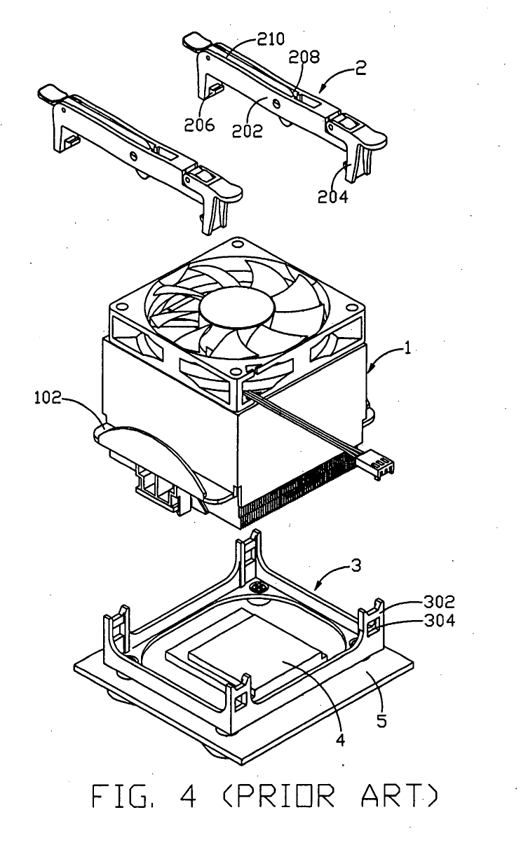

Referring also to FIG. 2, each retainer 30 comprises a pressing section 32, an operating section 34 extending upwardly from one end of the pressing section 32, and a cantilever locking section 36 stamped upwardly from the pressing section 32. A through hole 40 is defined in the pressing section 32 between the operating section 34 and the locking section 36. The diameter of the through hole 40 is larger than the one of the head 27 of the post 26. The locking section 36 extends slantwise from the pressing section 32 in a direction away from the operating section 34. The locking section 36 comprises an approximately V-shaped locking portion 38 formed at a free end thereof and spaced from the pressing section 32. A slot 42 is defined in the locking section 36 and communicates with the through hole 40. The width of the slot 42 is larger than the diameter of the neck 28 of the post 26 but smaller than the diameter of the head 27 of the post 26.

Referring to FIG. 3, in assembly, the back plate 20 is mounted below the printed circuit board 60 with the posts 26 of the back plate 20 extending through the respective through holes 62 of the printed circuit board 60. The heat sink 10 is placed on the CPU 50 with the posts 26 extending through the holes 16 of the heat sink 10 respectively. The retainers 30 are placed on the respective mounting sections 15 of the heat sink 10 to allow the posts 26 to extend respectively through the through holes 40 of the retainers 30. The operating sections 34 of the retainers 30 are pulled in a direction away from the heat sink 10 to cause the necks 28 of the corresponding posts 26 to slide in the slots 42 of the retainers 30 until they reach the ends of the slots 42. The heads 27 of the posts 26 seat on the locking portions 38 of the respective retainers 30 and the necks 28 of the posts 26 are therefore engaged with the locking portion 38 at the ends of the slots 42. The locking sections 36 are downwardly pressed by the heads 27 of the posts 26 and therefore elastically deforms. Accordingly, the locking section 36 of each retainer 30 exerts upward force to the head 27 of the post 26 and simultaneously the pressing section 32 exerts downward force to the base 12 of the heat sink 10 whereby the base 12 intimatly contacts with the CPU 50. Thus, the locking device firmly mounts the heat sink 10 to the CPU 50.

In disassembly, the operating sections 34 of the retainers 30 are pushed toward the heat sink 10 until the heads 27 of the posts 26 slide away from the corresponding locking portions 38 and enter into the through holes 40 of the retainers 30. After that, the back plate 20 is readily detached from the printed circuit board 60.

In the preferred embodiment, no retention module is required for cooperating with the locking device to secure the heat sink 10. The locking device consists of four separate retainers 30 each having a small size. The retainers 30 rest on the mounting sections 15 of the base 12 of the heat sink 10 without crossing through the base 12 and occupy small spaces above the base 12, whereby only a small amount of heat dissipating area of the heat sink 10 is sacrificed.

It is understood that the invention may be embodied in other forms without departing from the spirit thereof. Thus, the present example and embodiment is to be considered in all respects as illustrative and not restrictive, and the invention is not to be limited to the details given herein.

1. A retainer for mounting a heat sink to an electronic component with plural of posts provided thereabout, the retainer comprising:
a pressing section adapted for resting on the heat sink;
an operating section extending from the pressing section; and
a locking section extending slantwise from the pressing section and defining a slot; wherein
a through hole is defined in the pressing section between the operating section and the locking section and communicates with the slot whereby one of the posts is capable of extending through the hole to interlock with the locking section at the slot.

2. The retainer as claimed in claim 1, wherein the locking section comprises a V-shaped locking portion formed at one end thereof.

3. The retainer as claimed in claim 2, wherein the locking section extends from the pressing portion in the manner of a cantilever.

4. The retainer as claimed in claim 3, wherein the locking section extends from the pressing section in a direction away from the operating section.

5. A combination comprising:
a circuit board with an electronic component mounted thereon;
a heat sink placed on the electronic component and comprising a base with a plurality of fins provided thereon; and
a locking device for mounting the heat sink on the electronic component, the locking device comprising:
a back plate mounted below the circuit board and comprising a plurality of posts extending upwardly through the circuit board and the heat sink; and
a plurality of separate retainers each comprising a pressing section resting on the base of the heat sink without crossing through the base, and a locking section extending from the pressing section and having a locking portion spaced from the base;
wherein each retainer is movable between a loose position in which one of posts is detachable from said retainer and a locked position in which said post is engaged with the locking portion of the retainer.

6. The combination as claimed in claim 5, wherein the base of the heat sink comprises a plurality of mounting sections formed at corners thereof on which the retainers rest and no fin is provided.

7. The combination as claimed in claim 6, wherein the pressing section defines a through hole and the locking section defines a slot communicating with the through hole.

8. The combination as claimed in claim 7, wherein the post forms a head on the top end thereof and a neck below the head, when the retainer is located in the loose position the post is freely extendable through the through hole and when the retainer is located in the locked position the neck of the post is engaged in the slot with the head of the post seated on the locking portion.

9. The combination as claimed in claim 8, wherein the locking portion is V-shaped.

10. The combination as claimed in claim 7, wherein the retainer further comprises an operating section extending from the pressing section, the hole being formed between the operating section and the locking section.

11. A locking device for mounting a heat sink onto an electronic component, comprising:
a plurality of posts located around said electronic component, each of said plurality of said posts retaining said electronic component by one end thereof, and another end of said each post extending toward said heat sink;
a retainer corresponding to said each post resting on a mounting portion of said heat sink at an edge thereof away from said electronic component, said retainer engaging with said another end of said each post at one position and disengaging from said another end at another position, and being flexible to exert flexible force to said another end of said each post and said mounting portion of said heat sink respectively in case of movement of said retainer from said one position to said another position.

12. The locking device as claimed in claim 11, wherein a back plate is installed at a side of said electronic component away from said heat sink, and said one end of said each post to retain said electronic component is connected to said back plate. The locking device as claimed in claim 11, wherein said one position of said retainer and said another position of said retainer are both located beside said mounting portion of said heat sink.
